(19) United States
(12) Patent Application Publication
(10) Pub. No.: US 2008/0056042 A1
(43) Pub. Date: Mar. 6, 2008

(54) STORAGE CAPACITY OPTIMIZATION IN HOLOGRAPHIC STORAGE MEDIA

(75) Inventor: Michael Leonhardt, Longmont, CO (US)

Correspondence Address: SUN MICROSYSTEMS, INC. c/o DORSEY & WHITNEY, LLP, 370 SEVENTEENTH ST., SUITE 4700, DENVER, CO, 80202, US

(73) Assignee: Sun Microsystems, Inc., Santa Clara, CA (US)

(21) Appl. No.: 11/468,489

(22) Filed: Aug. 30, 2006

(51) Int. Cl. G11C 13/04

(52) U.S. Cl. 365/216

(57) ABSTRACT

Methods and systems are provided for storing data holographically. Multiple distinct data packets are received. The data packets are stored on a temporary data storage. Data that includes the data packets are written holographically during a single write session to a photopolymer storage medium by optically interfering an optical data beam with an optical reference beam. The data are written physically to a data region on the photopolymer storage medium. A bleaching area of the photopolymer storage medium is exposed to a bleaching illumination to optically fix the bleaching area and prevent data from subsequently being written to the bleaching area. The bleaching area includes the data region.

### BACKGROUND OF THE INVENTION

This application relates generally to data storage. More specifically, this application relates to data storage in holographic storage media.

It is well known that the capacity of electronic data storage elements has been increasing steadily, with a doubling of capacity for such elements occurring on the order of every two to three years. In parallel with these developments, there has been a persistent demand to store and archive ever increasing amounts of data. Driven by this need for increasing storage capacity, researchers have investigated a number of different types of media and different ways of storing information on those media. These efforts have generally taken place largely in isolation from the actual use of the different storage media and their integration into larger storage systems as researchers have focused on addressing physical challenges in storing larger amounts of data.

The actual use of different types of storage media within a comprehensive data-storage environment presents its own set of issues. These issues derive not only from the raw storage capacity of individual media, but also from the need to ensure that that storage capacity is used efficiently, that data are written to the media efficiently, that the storage media can be archived within the environment effectively to allow easy retrieval of information, and the like.

There is accordingly a continued need in the art for increasing storage capacities of media, particularly in ways that accommodate the mechanics of using particular media in data-storage environments.

### BRIEF SUMMARY OF THE INVENTION

Embodiments of the invention provide methods and systems for storing data holographically. A plurality of distinct data packets are received. The data packets are stored on a temporary data storage. Data comprising the plurality of data packets are written holographically during a single write session to a photopolymer storage medium by optically interfering an optical data beam with an optical reference beam. The data are written physically to a data region comprised by the photopolymer storage medium. A bleaching area of the photopolymer storage medium is exposed to a bleaching illumination to optically fix the bleaching area and prevent data from subsequently being written to the bleaching area. The bleaching area comprises the data region.

In some embodiments, the data may be written holographically in response to a predetermined condition being satisfied. For example, the predetermined condition may comprise a determination that the plurality of data packets have a combined size that exceeds a predetermined size. The data written holographically to the photopolymer storage medium may be generated by organizing the plurality of data packets according to a desired performance criterion. In different embodiments, the distinct data packets may be received substantially simultaneously or may be received at substantially different times. In some instances, the photopolymer storage medium is archived in a data-storage system.

In one embodiment, further data may be written to the photopolymer storage medium. A second plurality of distinct data packets are received and stored on the temporary data storage. Second data comprising the second plurality of data packets are written holographically during a single write session to the photopolymer storage medium by optically interfering a second optical data beam with a second optical reference beam. the second data are written physically to a second data region comprised by the photopolymer storage medium. A second bleaching area of the photopolymer storage medium is exposed to a bleaching illumination to optically fix the second bleaching area and prevent data from subsequently being written to the second bleaching area. The second bleaching area comprises the second data region. In another embodiment, the photopolymer storage medium acts as a single-session write device. The data region comprises a majority of the photopolymer storage medium and the bleaching area consists essentially of an entirety of the photopolymer storage medium.

Methods of the invention may be embodied in a data-storage system that comprises a host system, a temporary data-storage device, a data-storage archive, and a holographic drive. The data-storage archive can include robotic-enabled media handling and/or manually enabled media handling. The host system is in communication with the temporary data-storage device, the data-storage archive, and the holographic drive. The host system also comprises a computer-readable medium having a computer-readable program embodied therein for directing operation of the data-storage system in accordance with the description above. In one embodiment, the temporary data-storage device comprises a magnetic disk array. In some instances, the data-storage system further comprises a robotic system in communication with the host system, with the computer-readable program having instructions to archive the written photopolymer storage medium in the data-storage archive by operating the robotic system to move the written photopolymer storage medium to a defined location in the data-storage archive. When a request is received for at least a portion of one of the data packets stored on the photopolymer storage medium, the robotic system is operated to retrieve the written photopolymer storage medium from the defined location in the data-storage archive and retrieve the portion of the one of the data packets holographically with the holographic drive.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 provides a schematic illustration of windage resulting from fixing holographically stored information on a photopolymer storage medium;

FIGS. 2A and 2B provide schematic illustrations of structures that may be used in providing a data-storage system in accordance with embodiments of the invention;

FIG. 3 is a flow diagram illustrating methods of the invention in some embodiments; and

FIG. 4 is a schematic illustration of an exemplary structure for a holographic drive.

### DETAILED DESCRIPTION OF THE INVENTION

One type of storage medium that has been attracting increasing attention because of its large storage capacity uses holographic storage as a specific form of optical data storage. Briefly, a typical technique for storing data holographically uses two coherent light beams and directs them onto a storage medium; in some instances the two beams may originate as a single laser beam that is split by a partially reflective mirror or other optical beamsplitter. One of the coherent beams is a signal beam that is used to encode the data on the storage medium while the other coherent beam is a reference beam. An interference pattern is produced within the storage medium where the beams intersect and stored on the storage medium. The data may subsequently be retrieved by illuminating the storage medium with a beam substantially identical to the reference beam, with the stored interference pattern causing light to be diffracted and reproduce the data beam.

There are two broad classes of materials that have been used to provide the holographic storage medium: photorefractive crystals such as LiNbO₃ or BaTiO₃, which record the interference pattern by locally changing their refractive index; and photopolymers, which record the inference pattern in the form of induced photochemical changes in a film. The photopolymer typically comprises a dopant chromophore embedded within a polymer matrix, with two gratings being formed when illuminated, one grating corresponding to the chromophores that are attached to the polymer matrix and the other grating corresponding to the chromophores that are not attached to the matrix.

Photopolymer storage media have been increasing in popularity and are believed likely to be the more widely used media for holographic data storage. With such photopolymer media, recording of the interference pattern is followed by a curing step in which the region of the medium written to is exposed to a beam of light to exhaust any remaining photoactive species in the material and thereby fix the image by eliminating the ability to write any additional data to that region. This process is sometimes referred to herein as “bleaching” the region and commonly uses a different wavelength of light than was used in producing the interference pattern, but this is not required and the same wavelength may be used. With some photopolymeric materials, this bleaching may additionally be followed by a brief heating step. An entire sequence of writing data to the storage medium and fixing it with a bleaching step and perhaps also a heating step is referred to herein as a “session.”

The inventor was tasked with investigating how to incorporate this type of photopolymer storage media into a system-level data-storage configuration, and particularly with how to use these media to store as much data as possible. Thus, rather than focusing on the physical and photochemical effects that govern how the data are written and the theoretical limits that might exist to storing data on such media, the inventor was directing attention to how the medium would actually be used within a system-level configuration.

One observation that the inventor made was that, with a certain irony, the very large data-storage capacity of photopolymer media acted to reduce the efficiency with which data were stored. He identified this as a consequence of a combination of the fact that many data-storage sessions involve the writing of significantly less data than the capacity of the storage medium and the fact that each session results in some loss of capacity. In many instances, the number of sessions used to fill a photopolymer storage medium holographically may be large, resulting in a multiplicatively significant loss of capacity.

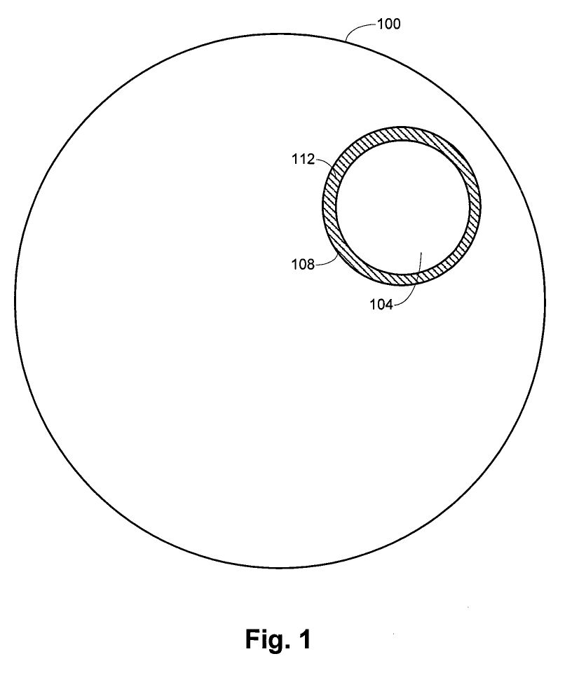

The loss of capacity that results from each session may be understood with reference to FIG. 1, which provides a schematic illustration of a photopolymer storage medium 100 with a region 104 on which data have been written holographically. A larger area 108 surrounding the region 104 corresponds to the area of the photopolymer storage medium that is exposed to the bleaching illumination. This bleaching area 108 is selected to comprise at least the entirety of the data region 104 and includes some windage to accommodate the fact that the beam boundaries provided by the bleaching illumination are generally not distinct, reflecting instead a power gradient and beam-alignment tolerances. In the drawing, this windage is illustrated with a hatched annular region between the data region 104 and the bleaching area 108.

It should be appreciated that the representation in FIG. 1 is somewhat idealized in that the data region 104 and bleaching area 108 are shown as concentric circular regions, but there is no such requirement. More generally, the data region 104 and bleaching area 108 may have other shapes and the size of the windage pattern may vary around the periphery of the data region 104. It is, however, a general characteristic of the method of writing data holographically to photopolymer storage media that there is some windage, and that the resulting loss of useable area on the storage medium may increase with the number of writing sessions.

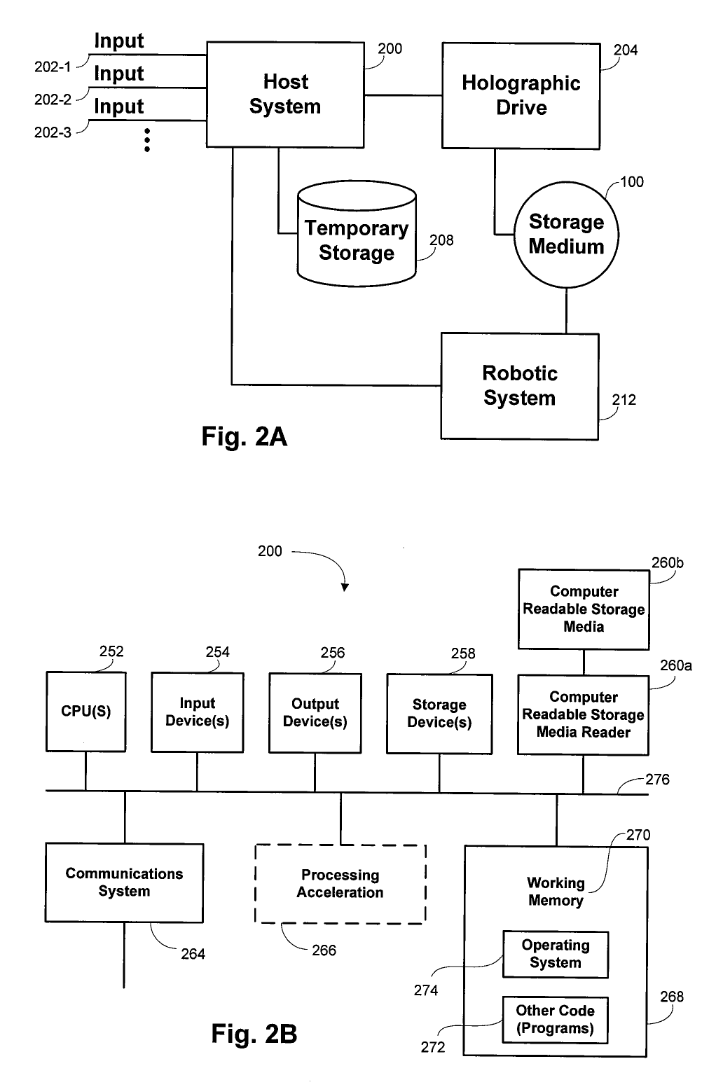

Embodiments of the invention accordingly integrate a holographic drive used for writing data to a photopolymer storage medium into a data-storage system that includes sufficient temporary storage to buffer data before writing it to the medium. This reduces the number of times that data are written to the medium, with data being written only a single time to the medium in particular embodiment, and thereby also reducing the unused area of the medium in an embodiment where it acts as a single-session write device. An schematic illustration of one exemplary system that includes such an integration is provided in FIG. 2A. Operation of the storage system is generally coordinated by a host system 200, which is shown having a number of interfaces 202 that may provide data input when the host system 200 is functioning to write data holographically to a photopolymer storage medium 100, although the host system 200 may also perform other functions using the interfaces in other embodiments. For example, the host system 200 may perform a variety of different functions that manage the operations of the data-storage system, such as by receiving requests for data, responding to such requests by activating components to retrieve the data, maintaining records of where data are stored, and the like, in addition to responding to requests to store data. Furthermore, although the discussion below focuses on those aspects of the system that are relevant to holographic storage of data, the storage system may additionally accommodate the storage of data on other types of media, including various forms of disks or tapes for magnetic data storage and/or the use of alternative forms of optical data storage, with the host system 200 having corresponding functionality to accommodate such additional forms. In certain embodiments, the host system 200 may thus comprise a front-end virtualization engine.

The actual manipulation of physical media is generally handled by a robotic system 212 under the control of the host system 200. System 212 can comprise host system 200 generated media-handling instructions communicated to and carried out by a human operator. For example, the robotic system 212 may be provided with instructions from the host system 200 to move particular media identified by the host system 200 from archival locations to read or write stations when data are to be read from or written to the media. Thus, when data are to be written holographically to a photopolymer storage medium 100, the robotic system 212 may be instructed to move the medium 100 for access by a holographic drive 204, also provided under the coordinating control of the host system 200. The holographic drive 204 is instructed to write a collection of data that have been buffered in a temporary storage 208 from multiple separate data packets onto the photopolymer medium 100, thereby limiting the number of write functions performed with that medium 100. The temporary storage 208 may comprise any type of storage device capable of storing amounts of data that correspond to a significant fraction of the storage capacity of the photopolymer medium. Specifically, in different embodiment, the temporary storage 208 is capable of storing greater than 50 gigabytes (“GB”) of data, is capable of storing greater than 100 GB of data, is capable of storing greater than 200 GB of data, is capable of storing greater than 500 GB of data, or is capable of storing greater than 1000 GB of data. In one embodiment, the temporary storage 208 comprises a magnetic disk array. In another embodiment, the temporary storage 208 comprises solid-state storage.

FIG. 2B broadly illustrates a structure that may be used for the host system 200 used in combination with other system elements. Individual system elements may be implemented in a separated or more integrated manner. The host system 200 is shown comprised of hardware elements that are electrically coupled via bus 276. The hardware elements include a processor 252, one or more input devices 254 such as may be coupled with interfaces 202, one or more output devices 256, one or more local storage devices 258, including the temporary storage device 208, a computer-readable storage media reader 260a, a communications system 264, a processing acceleration unit 266 such as a DSP or special-purpose processor, and a memory 268. The computer-readable storage media reader 260a is further connected to a computer-readable storage medium 260b, the combination comprehensively representing remote, local, fixed, and/or removable storage devices plus storage media for temporarily and/or more permanently containing computer-readable information. The communications system 264 may comprise a wired, wireless, modem, and/or other type of interfacing connection and permits data to be exchanged with external devices.

The host system 200 also comprises software elements, shown as being currently located within working memory 270, including an operating system 274 and other code 272, such as a program designed to implement methods of the invention. It will be apparent to those skilled in the art that substantial variations may be used in accordance with specific requirements. For example, customized hardware might also be used and/or particular elements might be implemented in hardware, software (including portable software, such as applets), or both. Further, connection to other computing devices such as network input/output devices may be employed.

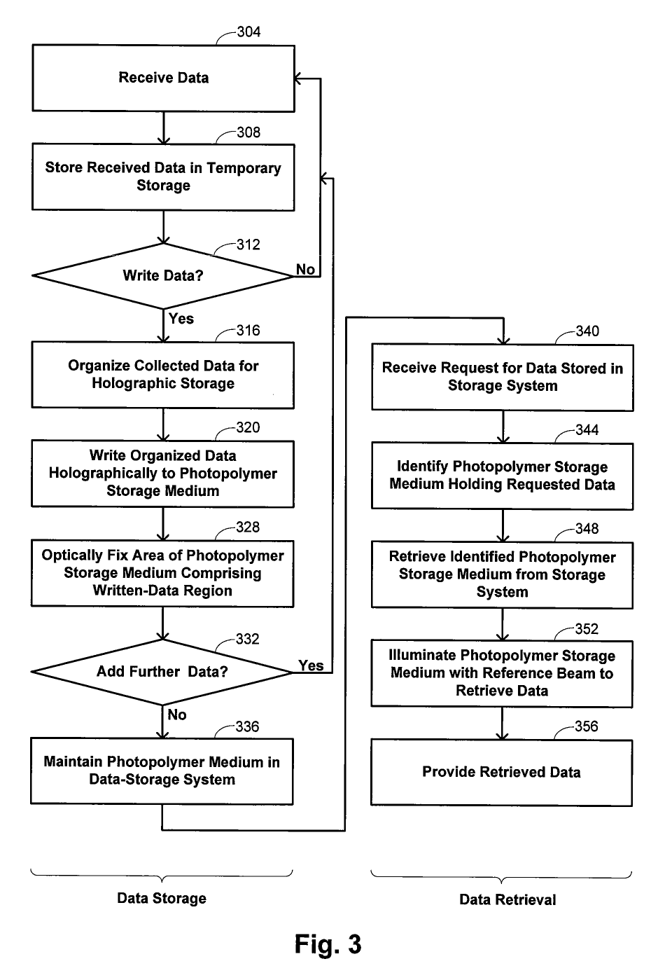

Methods of the invention may be more fully understood with reference to FIG. 3, which provides a flow diagram summarizing various aspects of the invention in certain embodiments. The left column of the drawing illustrates how data may be stored on a photopolymer storage medium, particularly in applications where such storage functions are implemented within a comprehensive data-storage system, while the right column of the drawing illustrates how data may be retrieved from a photopolymer storage medium maintained in such a data-storage system. Embodiments of the invention limit the amount of space unused as a result of the bleaching function by accumulating multiple packets of data and writing them during a single write session to the photopolymer storage medium. Data are thus received as a plurality of distinct packets at block 304 and stored in the temporary storage 208 at block 308 until criteria for writing the collected data are met. A check is made whether such criteria have been met at block 312, with data continuing to be received and buffered in the temporary storage 208 as long as the criteria that trigger writing of the data remain unmet. The receipt of a plurality of distinct packets at block 304 may thus occur substantially simultaneously in some embodiments or may occur as temporally separated events in other embodiments where satisfaction of the criteria to trigger writing of the data involve some passage of time.

There are numerous different types of criteria that may be imposed at block 312, some of which are described herein for exemplary purposes without intending to limit the scope of the invention. For example, one criterion that may be imposed requires that the collected data have a certain total size that exceeds a predetermined limit, such as 50 GB, 100 GB, 200 GB, 500 GB, or 1000 GB. Imposition of such a criterion advantageously ensures that at least a certain fraction of the photopolymer storage medium is allocated to data storage. For instance, the criterion might specify that the write function be performed when a certain predetermined data size is met to ensure that each photopolymer medium is written to only once. In some embodiments, the writing criteria may be chosen directly to include a temporal requirement, such as by having data written at periodic intervals, say once every day or once every hour depending on the data-storage environment. In still other embodiments, the size and temporal requirements might be combined, such as by triggering a write function whenever the collected data exceed a certain predetermined size, while also triggering a write function of any collected but unwritten data according to a periodic schedule. The criteria imposed at block 312 might also discriminate different types of data, causing certain types of data to be written when a size criterion is satisfied, but causing other types of data to be written according to a periodic schedule. Still other criteria for triggering the write function will be evident to those of skill in the art.

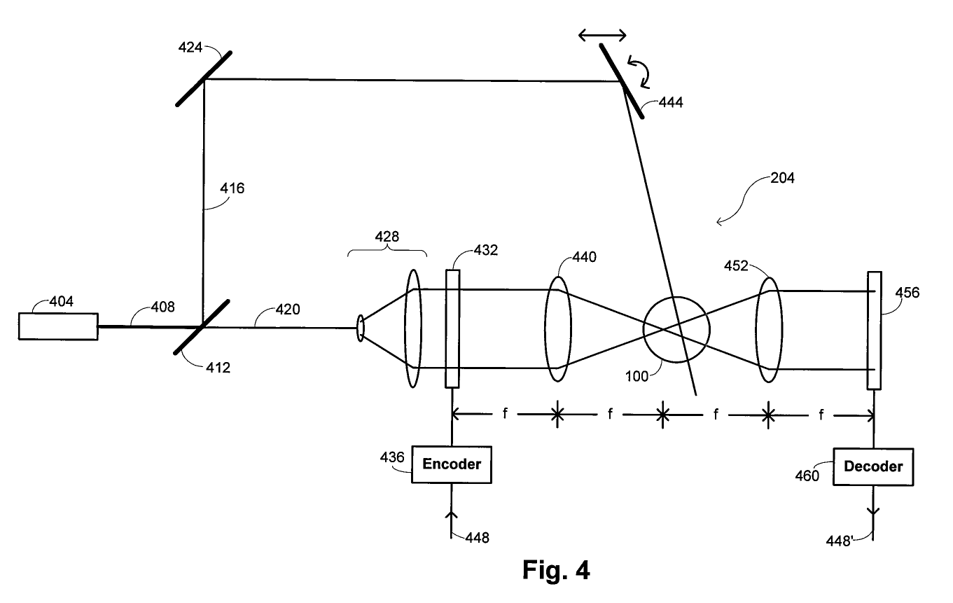

Once the criteria at block 312 have been met, writing the data may begin by organizing the collected data for holographic storage. Because the collected data originate as a plurality of distinct data packets, it may be advantageous to perform such organization and thereby improve either the writing of the data itself or its later retrieval from the storage system. The manner in which the organization is performed may depend on the type of data, the relationships between the different packets of data, and similar characteristics, with the organization being geared to optimizing performance as measured by such features as write rates, read rates, access times, and the like. The organized data are written holographically to the photopolymer storage medium at block 320, a further description of which is provided for one possible configuration in connection with FIG. 4. At block 328, a bleaching function is performed to optically fix a region of the photopolymer storage medium that comprises the region in which the organized data were written. Performing this function may comprise exposing the bleaching region to illumination that eliminates the capability of writing additional optical data to the region.

Depending on the criteria that were applied at block 312 to trigger the write function and/or the actual size of the data written at block 320, it may or may not be possible or desirable for further data to be written to the photopolymer storage medium. If so, as checked at block 332, further data packets are received at block 304, with the method being repeated until no further data are to be written to that storage medium. At that point, the written photopolymer medium may be maintained in an archival location within the data storage system, as indicated at block 336. Such maintenance typically includes recording an inventory of the data that have been recorded so that the host system 200 may issue instructions to retrieve the particular data when desired.

The archived storage medium may then be used in a manner similar to any other form of archived storage medium, including magnetic tape, magnetic disks, or another form of optical data storage, with mechanisms being provided to retrieve the data efficiently. For instance, if a particular piece of data stored on the photopolymer medium is requested at block 340, the host system 200 may identify the particular photopolymer medium using its inventory at block 344. It may issue instructions to the robotic system 212 at block 348 to retrieve the identified storage medium, which may then be illuminated at block 352 with a reference beam to recover the holographically stored data. The retrieved data may then be provided at block 356 to satisfy the request received at block 340.

While the invention is not limited to any particular structure for the holographic drive 204, a general overview is provided in FIG. 4 of a structure that may be used to perform holographic writing and reading functions in some embodiments. The arrangement illustrated in FIG. 4 is one example of a 4f holographic drive. In this embodiment, the drive 204 includes a source of coherent illumination, such as a laser light source 404 that provides a beam 408 of the coherent illumination incident on a beamsplitter 412. The beamsplitter 412 might comprise a partially reflective and partially transmissive mirror so that a first beam 420 is directed as a signal light beam 420 to a beam expander 428 and a second light beam 416 is directed through optical routing structure as a reference beam.

After expansion by the beam expander 428, the signal beam encounters a spatial light modulator 432, where it is optically modulated in accordance with a pattern provided by an encoder 436 defined by recording data 448. This encoded pattern may be received by the spatial light modulator 432 as an electrical signal, forming a pattern of light and dark dots on a plane to define a dot-pattern representation of the recording data. The modulated beam is then transmitted through a Fourier-transformation lens 440 separated by its focal length f from the spatial light modulator 432 so that the dot-pattern representation is subject to a Fourier transformation and focused onto the photopolymer storage medium 100. At the same time, the reference beam 416 is directed to the photopolymer storage medium 100 where it interferes with the Fourier-transformed beam to generate a holographic representation of the encoded signal. In the illustrated embodiment, the reference beam 416 is directed by an optical routing structure that includes a fixed mirror 424 and a moveable mirror 444, although other structures may be used in different embodiments. The moveable mirror 444 may have two degrees of freedom to permit it to be translated and rotated, and thereby direct the reference beam to different portions of the storage medium 100. The interference pattern is then recorded on the photopolymer medium.

The information stored in this way may be recovered by a reverse process, namely by later irradiating the written storage medium with the reference beam 416. This may be accomplished with the structure of FIG. 4 by having the spatial light modulator 432 block transmission of the signal beam 420, although other techniques may be used in alternative embodiments. Irradiation of the holographically written medium 100 with the reference beam 416 causes a reproduction of the recorded interference pattern to be generated on the opposite side of the storage medium 100, permitting the dot-pattern representation to be recovered by reverse Fourier transformation using a second Fourier-transformation lens 452 having focal length f and detected by a photodetector 456 separated from the second Fourier-transformation lens 452 by f. The detected dot-pattern representation may then be electrically decoded by a decoder 460 to form a counterpart 448′ to the original recording data 448.

Thus, having described several embodiments, it will be recognized by those of skill in the art that various modifications, alternative constructions, and equivalents may be used without departing from the spirit of the invention. Accordingly, the above description should not be taken as limiting the scope of the invention, which is defined in the following claims.

What is claimed is:

1. A method of storing data holographically, the method comprising:
receiving a plurality of distinct data packets;
storing the data packets on a temporary data storage;
holographically writing data comprising the plurality of data packets during a single write session to a photopolymer storage medium by optically interfering an optical data beam with an optical reference beam, wherein the data are written physically to a data region comprised by the photopolymer storage medium; and
exposing a bleaching area of the photopolymer storage medium to a bleaching illumination to optically fix the bleaching area and prevent data from subsequently being written to the bleaching area, wherein the bleaching area comprises the data region.

2. The method recited in claim 1 wherein holographically writing the data is performed in response to a predetermined condition being satisfied.

3. The method recited in claim 2 wherein the predetermined condition comprises a determination that the plurality of data packets have a combined size that exceeds a predetermined size.

4. The method recited in claim 3 wherein the predetermined size is greater than or equal to 50 gigabytes.

5. The method recited in claim 1 further comprising generating the data written holographically to the photopolymer storage medium by organizing the plurality of data packets according to a desired performance criterion.

6. The method recited in claim 1 wherein receiving the plurality of distinct data packets comprises receiving the distinct data packets at substantially different times.

7. The method recited in claim 1 further comprising:
receiving a second plurality of distinct data packets;
storing the second plurality of data packets on the temporary data storage;
holographically writing second data comprising the second plurality of data packets during a single write session to the photopolymer storage medium by optically interfering a second optical data beam with a second optical reference beam, wherein the second data are written physically to a second data region comprised by the photopolymer storage medium; and
exposing a second bleaching area of the photopolymer storage medium to a bleaching illumination to optically fix the second bleaching area and prevent data from subsequently being written to the second bleaching area, wherein the second bleaching area comprises the second data region.

8. The method recited in claim 1 wherein the data region comprises a majority of the photopolymer storage medium and the bleaching area consists essentially of an entirety of the photopolymer storage medium, whereby the photopolymer storage medium acts as a single-session write device.

9. The method recited in claim 1 further comprising archiving the photopolymer storage medium in a data-storage system.

10. A data-storage system comprising:
a host system;
a temporary data-storage device;
a data-storage archive; and
a holographic drive,
wherein the host system is in communication with the temporary data-storage device, the data-storage archive, and the holographic drive and comprises a computer-readable medium having a computer-readable program embodied therein for directing operation of the data-storage system, the computer-readable program including:
instructions to receive a plurality of distinct data packets with the host system;
instructions to store the data packets on the temporary data-storage device;
instructions to holographically write data comprising the plurality of data packets during a single write session to a photopolymer storage medium with the holographic drive, wherein the data are written physically to a data region comprised by the photopolymer storage medium;
instructions to expose a bleaching area of the photopolymer storage medium to a bleaching illumination with the holographic drive to optically fix the bleaching area and prevent data from subsequently being written to the bleaching area, wherein the bleaching area comprises the data region; and
instructions to archive the written photopolymer storage medium in the data-storage archive.

11. The data-storage system recited in claim 10 wherein the instructions to holographically write the data are executed in response to a predetermined condition being satisfied.

12. The data-storage system recited in claim 11 wherein the predetermined condition comprises a determination that the plurality of data packets have a combined size that exceeds a predetermined size.

13. The data-storage system recited in claim 12 wherein the predetermined size is greater than or equal to 50 gigabytes.

14. The data-storage system recited in claim 10 wherein the computer-readable program further includes instructions to generate the data written holographically to the photopolymer storage medium by organizing the plurality of data packets according to a desired performance criterion.

15. The data-storage system recited in claim 10 wherein the computer-readable program further includes:
instructions to receive a second plurality of distinct data packets with the host system;
instructions to store the second plurality of data packets on the temporary data-storage device;
instructions to holographically write second data comprising the second plurality of data packets during a single write session to the photopolymer storage medium with the holographic drive, wherein the second data are written physically to a second data region comprised by the photopolymer storage medium; and
instructions to expose a second bleaching area of the photopolymer storage medium to a bleaching illumination with the holographic drive to optically fix the second bleaching area and prevent data from subsequently being written to the second bleaching area, herein the second bleaching area comprises the second data region.

16. The data-storage system recited in claim 10 wherein the data region comprises a majority of the photopolymer storage medium and the bleaching area consists essentially of an entirety of the photopolymer storage medium, whereby the photopolymer storage medium acts as a single-session write device.

17. The data-storage system recited in claim 10 wherein the temporary data-storage device comprises a magnetic disk array.

18. The data-storage system recited in claim 10 further comprising a robotic system in communication with the host system, wherein the instructions to archive the written photopolymer storage medium in the data-storage archive comprise instructions to operate the robotic system to move the written photopolymer storage medium to a defined location in the data-storage archive.

19. The data-storage system recited in claim 18 wherein the computer-readable program further includes:
instructions to receive a request for at least a portion of one of the data packets with the host system;
instructions to operate the robotic system to retrieve the written photopolymer storage medium from the defined location in the data-storage archive; and
instructions to retrieve the portion of the one of the data packets from the written photopolymer storage medium holographically with the holographic drive.

20. A method of storing data holographically, the method comprising:
receiving a plurality of distinct data packets;
storing the data packets on a temporary data storage;
determining that the plurality of data packets have a combined size that exceeds a predetermined size, the predetermined size being greater than or equal to 50 gigabytes;
organizing the plurality of data packets according to a desired performance criterion;
holographically writing data comprising the organized data packets during a single write session to a photopolymer storage medium by optically interfering an optical data beam with an optical reference beam, wherein the data are written physically to a data region comprised by the photopolymer storage medium;
exposing a bleaching area of the photopolymer storage medium to a bleaching illumination to optically fix the bleaching area and prevent data from subsequently being written to the bleaching area, wherein the bleaching area comprises the data region; and
archiving the written photopolymer storage medium in a data-storage system.

21. The method recited in claim 20 wherein the data region comprises a majority of the photopolymer storage medium and the bleaching area consists essentially of an entirety of the photopolymer storage medium, whereby the photopolymer storage medium acts as a single-session write device.
